(19) United States
(12) Patent Application Publication
(10) Pub. No.: US 2025/0086346 A1
(43) Pub. Date: Mar. 13, 2025

(54) AUGMENTED REALITY (AR) ASSISTED DIE MAKING SYSTEM

(71) Applicant: Ford Global Technologies, LLC, Dearborn, MI (US)

(72) Inventors: Raj Sohmshetty, Canton, MI (US); Elizabeth Bullard, Royal Oak, MI (US); Chris Schultz, Milford, MI (US); Jeff Tornabene, Canton, MI (US); Martin Smets, Lasalle (CA); Jian Wan, Novi, MI (US); Lorne Forsythe, Wind Lake, WI (US); Kyle Saul, Royal Oak, MI (US); Ramesh Parameswaran, Farmington Hills, MI (US)

(73) Assignee: Ford Global Technologies, LLC, Dearborn, MI (US)

(21) Appl. No.: 18/463,017

(22) Filed: Sep. 7, 2023

(51) Int. Cl. G06F 30/20; G06F 30/10; G06T 19/00; G06T 19/20; G06V 10/25; G06V 10/54

(52) U.S. Cl. CPC G06F 30/20; G06F 30/10; G06T 19/006; G06T 19/20; G06V 10/25; G06V 10/54; G06T 2219/2012

(57) ABSTRACT

A method of performing a finishing operation on a surface of a component includes: acquiring, by a sensing system, an image of the surface of the component; retrieving a CAD model of the surface of the component; comparing the image of the surface of the component with the CAD model of the surface of the component; determining at least one target area on the surface of the component where a difference in a geometry between the image and the CAD model of the surface of the component exceeds a threshold; and displaying at least one visual overlay corresponding to the at least one target area on a real-world content or a virtual content.

### CROSS-REFERENCE TO RELATED APPLICATION

This application is related to a co-pending application titled “System and Method for Robotic Assisted Die Surface Finishing,” concurrently filed herewith, the content of which is incorporated herein by reference in its entirety.

### FIELD

The present disclosure relates to a method of performing a finishing operation on a die.

### BACKGROUND

The statements in this section merely provide background information related to the present disclosure and may not constitute prior art.

In a die manufacturing process, finishing a die surface is the final step and typically performed by hand using honing stone and/or sandpaper. Manual polishing results depend on personal experience and crafting skills of each worker. The surface roughness of the manually-polished dies may not always satisfy the surface roughness requirement. The issues relating to finishing of a die surface by hand are addressed in the present disclosure.

### SUMMARY

This section provides a general summary of the disclosure and is not a comprehensive disclosure of its full scope or all of its features.

In one form of the present disclosure, a method of performing a finishing operation on a surface of a component is provided, which includes: acquiring, by a sensing system, an image of the surface of the component; retrieving a computer-aided design (CAD) model corresponding to the surface of the component; comparing the image of the surface of the component with the CAD model; identifying at least one target area on the surface of the component where a difference in a geometry between the image of the surface of the component and the CAD model exceeds a threshold; and displaying at least one visual overlay at a location corresponding to the at least one target area on a real-world content or a virtual content.

In other features, the virtual content may be, but not be limited to, a projector, a headset, glasses, contact lenses, a monitor, and an augmented reality (AR) display, or a combination thereof. The real-world content includes the surface of the component. The visual overlay has a color or a form indicating an amount of material to be removed by the finishing operation, or a selected finishing tool for the finishing operation. The at least one target area includes a plurality of target areas, and the at least one visual overlay includes a plurality of visual overlays in a plurality of colors corresponding to types of finishing operations to be formed on the plurality of target areas or corresponding to types of finishing tools to be used for the finishing operation.

In still other features, the method further includes: registering, by a processing device, the image of the surface of the component and the CAD model: outputting data relating to a type of a finishing tool for the finishing operation on the virtual content: generating a voice output with information relating to at least one of an amount of material to be removed from the at least one target area, a type of a finishing tool to be used for the finishing operation, and a type of the finishing operation; and performing real-time scanning of the surface of the component while performing the finishing operation on the surface of the component. The difference is a difference between a target surface roughness and a measured surface roughness. The component is a die.

In another form of the present disclosure, a method of performing a finishing operation on a surface of a component is provided, which includes: acquiring, by a sensing system, an image of the surface of the component; retrieving from a memory a computer-aided-design (CAD) model corresponding to the surface of the component; comparing the image of the surface of the component with the CAD model; identifying at least one target area on the surface of the component where a difference in a geometry between the image of the surface of the component and the CAD model exceeds a threshold; displaying at least one visual overlay at a location corresponding to the at least one target area on a real-world content or a virtual content; and outputting data relating to at least one of an amount of material to be removed from the at least target area, a selected finishing tool for the finishing operation, and a type of finishing operation to be performed.

In other features, the virtual content is selected from a group consisting of a projector, a headset, glasses, a monitor, and an augmented reality (AR) display. The real-world content includes the surface of the component. The data is displayed on the virtual content or output via a voice output. The method further includes performing real-time scanning to obtain real-time information relating to measured surface roughness. The visual overlay has a color or a form indicating an amount of material to be removed by the finishing operation and a selected finishing tool to be used for the finishing operation.

In still another form of the present disclosure, a non-transitory computer readable medium is provided, which includes instructions that, when executed by a processing device, cause the processing device to perform operations including; receiving an image of a surface of the component; retrieving a CAD model corresponding to the surface of the component; comparing the image of the surface of the component with the CAD model; identifying at least one target area on the surface of the component where a difference in a geometry between the image of the surface of the component and the CAD model exceeds a threshold; and displaying at least one visual overlay at a location corresponding to the at least one target area on a real-world content or a virtual content.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a schematic diagram of a die finishing system constructed in accordance with the teachings of the present disclosure;

FIG. 2 is a view of a die showing visual overlays being displayed directly on the die; and

FIG. 3 is a flow diagram of a method of performing a finishing operation on a die surface in accordance with the teachings of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

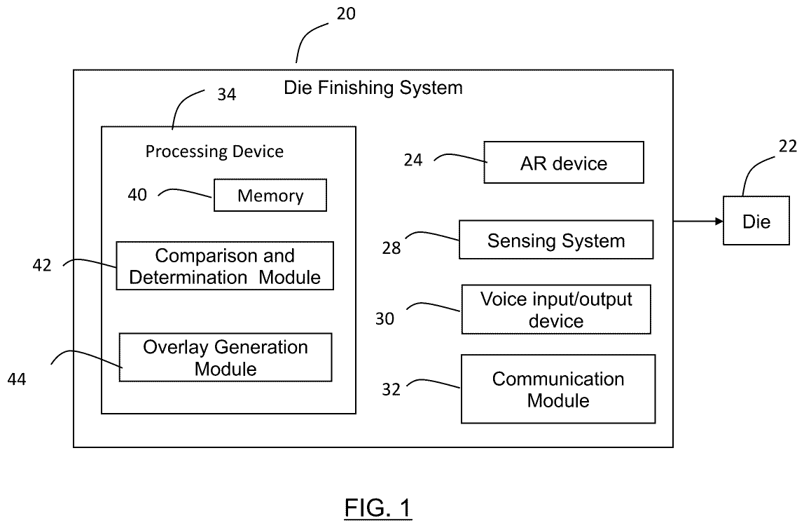

Referring to FIG. 1, a die finishing system 20 to aid an operator in performing a finishing operation on a surface of a die 22 in accordance with the teachings of the present disclosure includes an augmented reality (AR) device 24, a sensing system 28, a voice input/output device 30, a communication module 32, and a processing device 34. The processing device 34 includes a memory 40, a comparison and determination module 42, and an overlay generation module 44.

The sensing system 28 may include both vision-based and non-vision-based sensors. The vision-based sensors may include one or more cameras, such as a two-dimensional (2D) camera, a three-dimensional (3D) camera, a stereo vision camera, an infrared sensor, a radar scanner, a Stereo/RGB-D scanner, an optical scanner, a laser scanner, a blue light scanner, a light detection and ranging (LIDAR) sensor, and/or an ultrasonic sensor. The vision-based sensors are configured to scan the surface of the die 22 and acquire an image of the die surface based on the scanned data. The image of the die surface shows the global geometry of the die surface. As an example, the image may be acquired by the sensing system 28 based on scanned data acquired by blue light or laser scan.

The non-vision-based sensors of the sensing system 28 may include a plurality of sensors for measuring a contour/geometry/topology of the die surface, and surface roughness of the die 22. The non-vision-based sensors may also include laser or LIDAR profilometers for obtaining surface roughness of the die surface, and for obtaining measurements of local geometry, contour and topology of an area of the die surface (such as radius of a male portion or a radius of a female portion on the die surface, contour and geometry of target areas on which a polishing operation is to be performed). The non-vision-based sensors of the sensing system 28 may be used to obtain precise measurements of local areas of the die surface, whereas the vision-based sensors of the sensing system 28 may be used to obtain global geometry of the die surface to save time.

The communication module 32 is configured to allow communication among the various components of the die finishing system 20, via wires or wireless communication protocols, such as a Bluetooth®-type protocol, a cellular protocol, a wireless fidelity (Wi-Fi)-type protocol, a near-field communication (NFC) protocol, an ultra-wideband (UWB) protocol, among others. The data acquired by the sensing system 28 are transmitted to the processing device 38 via the communication module 32 for further processing and analysis.

The voice input/output device 30 may include a microphone and a speaker and is configured to receive voice commands from an operator via the microphone and to output via the speaker information about target areas on the die surface to be finished, a selected finishing tool and/or a selected finishing operation based on the analysis of the processing device 34.

The memory 40 is configured to store data relating to the finishing operations on the die 22. The data stored in the memory 40 may include, but be not limited to, CAD models of surfaces of various dies with target measurements and target surface roughness, a central tool library that map different types of finishing operations to a plurality of finishing tools. Different dies may have different surface roughness requirements. For example, one die from among the plurality of dies may require a Class A surface, whereas another die from among the plurality of dies 22 may require a Class B surface. A Class A surface is a visual surface with aesthetic look and has a curvature continuity without any features like ribs, snaps, bosses etc., and thus requires higher smoothness of the surface. A Class B surface refers to an invisible surface that may have features like rib, boss, snap etc. and has tangent continuity and thus has relatively large surface roughness. In addition, the CAD models for different dies may be classified as a Class A component (outer part) or a Class B component (inner part). The CAD models can also identify features as male or female parts, where only male features require better surface finish.

The comparison and determination module 42 is configured to: receive images from the sensing system 28; retrieve a CAD model corresponding to the die 22 to be finished from the memory 40; identify one or more target areas to be finished when a difference in the contour, geometry, or topology between the CAD model and the image from the vision system 28 exceeds a threshold. The images of the surface of the die acquired by the sensing system 28 show the current measurements of the die surface. The CAD models stored in the memory 40 show the target/desired measurements of the die surface.

The comparison and determination module 42 is configured to first match key points (such as male parts or female parts) with the CAD geometry to auto-calibrate and register the CAD model with the image of the die surface before performing the comparison. Based on the comparison, the target areas to be finished and the amount of material to be removed can be determined. The comparison and determination module 42 can also extract radii in critical regions using CAD or the scanned image. If the radii are smaller than certain value, the region requires better finish.

After the target area(s) are identified, the overlay generation module 44 generates and outputs one or more visual overlays 48 on a real-world content (such as the surface of the die 22), or a virtual content (including but not limited to a monitor, a projector, an AR device 24 including AR glasses, an AR headset, and contact lenses to be worn by an operator, and an AR display). It is understood that the overlay generation module 44 may include any wearable or nonwearable devices that can display the visual overlays 48 on the surface of the die 22 or on an image of the die 22 without departing from the scope of the present disclosure.

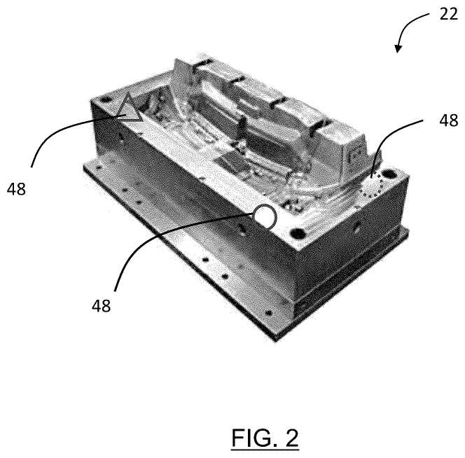

Referring to FIG. 2, a die 22 in an illustrative example is shown to be marked by a plurality of visual overlays 48. The visual overlays 48 may have a color or a form representing an amount of material to be removed, a particular type of finishing operation to be performed or a particular type of finishing tool to be used. The memory 40 may include a central tool library that map different types of finishing operations to a plurality of finishing tools. The plurality of finishing tools are operated to perform different types and grades of finishing operations including but not limited to grinding (for rough finishing), stoning (for Class A surface finishing), honing, polishing, buffing, sandblasting. The plurality of finishing tools may include grinding wheels, sand papers, honing stones, sanders and polishers having different grits for different grades of finish. The sand papers and the honing stones may be dry for rough finishing or immersed in oil for final finishing. Honing stones are generally used for Class A surface finishing. The finishing tools may also include a non-abrasive pad for removing dirt when the die surface is coated with a protective coating such as chrome.

In addition to identifying the target areas, the comparison and determination module 42 may be further configured to determine a desired finishing operation from among a plurality of finishing operations and determine a finishing tool from among the plurality of finishing tools to perform the desired finishing operation, based on the difference in geometry between the CAD model and the image of the die surface and the surface roughness requirement. The difference may be a difference between a target surface roughness and a measured surface roughness. Different target areas on the die surface may have different target roughness requirements and/or require different degrees of material removal. Therefore, the comparison and determination module 42 may further determine a desired finishing operation and a desired finishing tool for a particular target area. The desired finishing operation and finishing tool for a particular target area may be distinguished by displaying the visual overlays in different colors or forms.

After the comparison and determination module 42 determines the desired finishing operation, the desired finishing tool and/or the amount of material to be removed from a particular target area, this information may be output and also displayed on the real-world content or the virtual content. Additionally or alternatively, this information may be output as a voice output by the voice input/output device 30.

The overlay generation module 44 is configured to generate visual overlays 48 and output the visual overlays 48 at locations corresponding to the target areas on the real-world content or a virtual content. The display of the visual overlay 48 helps an operator identify the target area(s) that require a finishing operation, and select the right finishing tool for the finishing operation. It is understood that the visual overlays 48 may be displayed on any means at locations corresponding to the target areas of the die as long as the display of the overlay can help the operator identify the target area(s) that requires a finishing operation, without departing from the scope of the present disclosure.

During the finishing operation by the operator, the sensing system 28 acquires data about the die surface in real-time, and the processing device 34 also compares the image acquired by the sensing system 28 with the CAD model to provide updated data relating to the finishing operation, i.e., whether enough material has been removed and the finishing operation is complete or whether more material needs to be removed. Since the visual overlays 48 may be in different colors or forms depending on the amount of material to be removed, the colors and forms of the visual overlays 48 may be changed over time due to reduced amount of material to be removed during the finishing operation by the operator. When the comparison and determination module 42 determines, based on updated data from the sensing system 28, that a particular target area has a measured surface roughness within a predetermined (acceptable) range of the target surface roughness, the visual overlays 48 stop being displayed on the particular target area, indicating that the finishing operation is complete.

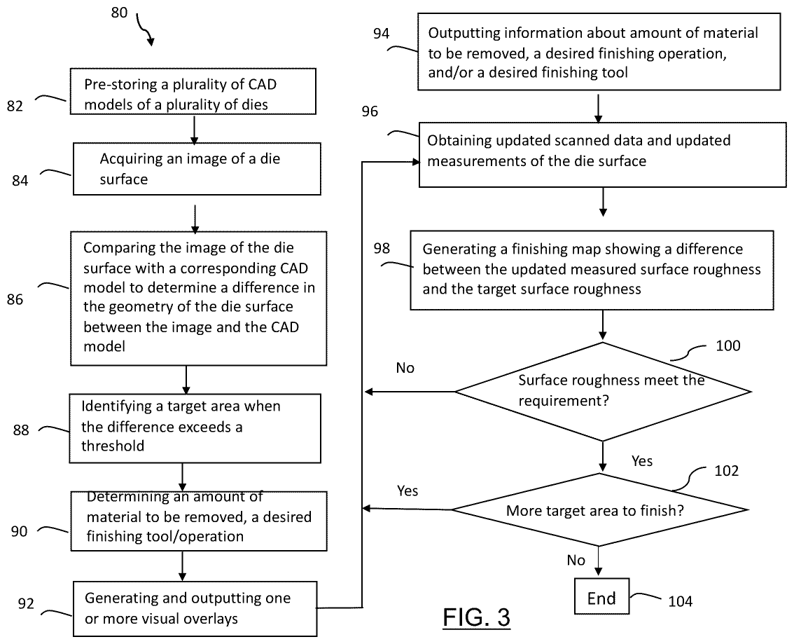

Referring to FIG. 3, a method 80 of performing a finishing operation on a surface of a die starts with pre-storing a plurality of CAD models for a plurality of dies having different dimensions and surface roughness requirements in step 82. Next, an image of the surface of an incoming die 22 is acquired in step 84. The image of the incoming die is compared with a corresponding CAD model to determine a difference in the geometry of the die surface between the image of the die surface and the CAD model in step 86. Then, the comparison and determination module 42 identifies one or more target areas that need to be finished when the difference in the geometry between the CAD model and the image of the die 22 exceeds a threshold in step 88. The comparison and determination module 42 may also determine the amount of the material to be removed from the target area, a desired finishing operation, and/or a desired finishing tool for the desired finishing operation in step 90.

Thereafter, the overlay generation module 44 generates and outputs a visual overlay 48 in step 92. The visual overly 48 may be displayed directly on a real-world content or a virtual content. Data relating to the amount of material to be removed from the target area, a desired finishing operation, and/or a desired finishing tool may also be output in step 94. The information may be displayed on the real-world content or the virtual content, or may be in the form of a voice by the voice input/output device 30. This information can guide the operator to select the right tool to perform the desired finishing operation.

During the finishing operation, updated scanned data and updated measurements of the die surface relating to the surface roughness of the target area and the geometry/contour of the die surface are obtained in step 96. A finishing map based on updated real-time scanned data is also generated in step 98. The finishing map may be in the form of a topographical map showing differences between the updated surface roughness and the target surface roughness. The topographical map provides an indication of the status of the finishing operation, i.e., whether the finishing operation is complete or whether further finishing operation is required. The topographical map may be displayed on the same AR device 24 or another display device to help the operator monitor the status of the finishing operation. When the measured surface roughness meets a predetermined value, i.e., within a predetermined range of the target surface roughness in step 100, the finishing operation for the particular target area is complete. When there are more target areas that require a finishing operation in step 102, the operator then moves on to perform another finishing operation on another target area and the method goes back to step 96. When no more target area needs a finishing operation, the method ends in step 104.

The finishing system 20 and the method of performing a finishing operation in accordance with the teachings of the present disclosure can guide and help an operator perform a finishing operation on a die by comparing the image of the die and the pre-stored CAD model of the die to identify one or more target areas that need to be finished. One or more visual overlays 48 are generated and displayed in the real-world content or a virtual content at locations corresponding to the target areas to help an operator identify the target areas. In addition, the finishing system 20 may also determine the amount of material to be removed from the targets areas, a desired finishing tool to be used, and a desired finishing operation to be performed and output this information to guide the operator to perform the finishing operation. This information may be displayed in a real-world content, in a virtual content or may be output via a voice output. Real-time surface scan of the die and measurements of the surface (such as surface roughness and measurement of geometry) on the target areas can be obtained during the finishing operation to provide information about the status of the finishing operation. The visual overlays may stop being displayed when the surface roughness of the target area is within a predetermined (acceptable) range.

It is understood that while the finishing system is described to perform a finishing operation on a die surface, the finishing system can be used, with or without modification, to perform other surface treating operation, such as electropolishing and chemical etching or shot blasting without departing from the scope of the present disclosure.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method of performing a finishing operation on a surface of a component, the method comprising:
acquiring, by a sensing system, an image of the surface of the component;
retrieving a computer-aided design (CAD) model corresponding to the surface of the component;
comparing the image of the surface of the component with the CAD model;
identifying at least one target area on the surface of the component where a difference in a geometry between the image of the surface of the component and the CAD model exceeds a threshold; and
displaying at least one visual overlay at a location corresponding to the at least one target area on a real-world content or a virtual content.

2. The method according to claim 1, wherein the virtual content is selected from a group consisting of a monitor, a projector, an augmented reality (AR) device.

3. The method according to claim 1, wherein the real-world content includes the surface of the component.

4. The method according to claim 1, wherein the visual overlay has a color or a form representing an amount of material to be removed by the finishing operation.

5. The method according to claim 1, wherein the visual overlay has a color a form representing a finishing tool for the finishing operation

6. The method according to claim 1, wherein the at least one target area includes a plurality of target areas, and the at least one visual overlay includes a plurality of visual overlays in a plurality of colors corresponding to types of finishing operations to be formed on the plurality of target areas.

7. The method according to claim 1, wherein the at least one target area includes a plurality of target areas, and the at least one visual overlay includes a plurality of visual overlays, and wherein the plurality of visual overlays are in a plurality of colors corresponding to types of finishing tools to be used for the finishing operation.

8. The method according to claim 1, further comprising registering, by a processing device, the image of the surface of the component and the CAD model.

9. The method according to claim 1, further comprising outputting data relating to a type of a finishing tool for the finishing operation on the virtual content.

10. The method according to claim 1, further comprising generating a voice output with information relating to at least one of an amount of material to be removed from the at least one target area, a type of a finishing tool to be used for the finishing operation, and a type of the finishing operation.

11. The method according to claim 1, wherein the difference is a difference between a target surface roughness and a measured surface roughness.

12. The method according to claim 1, further performing real-time scanning of the surface of the component while performing the finishing operation on the surface of the component.

13. The method according to claim 1, wherein the component is a die.

14. A method of performing a finishing operation on a surface of a component, the method comprising:
acquiring, by a sensing system, an image of the surface of the component;
retrieving from a memory a computer-aided-design (CAD) model corresponding to the surface of the component;
comparing the image of the surface of the component with the CAD model;
identifying at least one target area on the surface of the component where a difference in a geometry between the image of the surface of the component and the CAD model exceeds a threshold;
displaying at least one visual overlay at a location corresponding to the at least one target area on a real-world content or a virtual content; and
outputting data relating to at least one of an amount of material to be removed from the at least target area, a selected finishing tool for the finishing operation, and a type of finishing operation to be performed.

15. The method according to claim 14, wherein the virtual content is selected from a group consisting of a projector, a headset, glasses, contact lenses, a monitor, and an augmented reality (AR) display.

16. The method according to claim 14, wherein the real-world content includes the surface of the component.

17. The method according to claim 14, wherein the data is displayed on the virtual content or output via a voice output.

18. The method according to claim 14, further comprising performing real-time scanning to obtain real-time information relating to measured surface roughness.

19. The method according to claim 14, wherein the visual overlay has a color or a form indicating an amount of material to be removed by the finishing operation and a selected finishing tool to be used for the finishing operation.

20. A non-transitory computer readable medium comprising instructions that, when executed by a processing device, cause the processing device to perform operations comprising:
receiving an image of a surface of the component;
retrieving a CAD model corresponding to the surface of the component;
comparing the image of the surface of the component with the CAD model;
identifying at least one target area on the surface of the component where a difference in a geometry between the image of the surface of the component and the CAD model exceeds a threshold; and
displaying at least one visual overlay at a location corresponding to the at least one target area on a real-world content or a virtual content.
